(19) United States
(12) Patent Application Publication
(10) Pub. No.: US 2026/0303100 A1
(43) Pub. Date: Oct. 1, 2026

(54) ELECTRONIC DEVICE AND OPERATION METHOD THEREOF AND INTEGRATED CIRCUIT

(71) Applicant: MediaTek Singapore Pte. Ltd., Singapore (SG)

(72) Inventors: Junyan LI, Shenzhen (CN); Jing-Lin KUO, Hsinchu City (TW); Jie WANG, Shenzhen (CN)

(21) Appl. No.: 19/172,969

(22) Filed: Apr. 8, 2025

(30) Foreign Application Priority Data
Mar. 31, 2025 (CN) 202510399796.0

(51) Int. Cl. H03L 7/00; H03K 17/56

(52) U.S. Cl. CPC H03L 7/00; H03K 17/56

(57) ABSTRACT

An electronic device includes a processing unit and a plurality of integrated circuit units. The processing unit is configured to provide a register configuration in sequence. The integrated circuit units are configured to receive the register configuration in sequence. After all of the integrated circuit units have received the register configuration, the processing unit is configured to provide a sync signal to the integrated circuit units in parallel, or the last of the integrated circuit units is configured to provide the sync signal to the integrated circuit units in parallel. The integrated circuit units perform synchronization according to the sync signal.

### CROSS REFERENCE TO RELATED APPLICATIONS

This application claims priority of China Patent Application No. 202510399796.0, filed on Mar. 31, 2025, the entirety of which is incorporated by reference herein.

### BACKGROUND OF THE DISCLOSURE

### Field of the Disclosure

The disclosure relates to an electronic device, and, in particular, to an electronic device and an operation method thereof and an integrated circuit.

### Description of the Related Art

Generally, many wearable medical products require multiple ECG channels used in parallel. Similarly, a photoplethysmography (PPG) channel also needs to connect integrated circuits (ICs) in parallel to expand the sampling channels. However, the existing solutions are all single ECG channels, which only support single ECG signal leads, and may not guarantee complete synchronization of sampling, which is not conducive to high-precision algorithm analysis. Therefore, a new design for a circuit structure is needed to solve the problem described above.

### BRIEF SUMMARY OF THE DISCLOSURE

The disclosure provides an electronic device and an operation method thereof and an integrated circuit, thereby effectively achieving the synchronization of sampling of the integrated circuit units.

An embodiment of the disclosure provides an electronic device, which includes a processing unit and a plurality of integrated circuit units. The processing unit is configured to provide a register configuration in sequence. The integrated circuit units are configured to receive the register configuration in sequence. After all of the integrated circuit units have received the register configuration, the processing unit is configured to provide a sync signal to the integrated circuit units in parallel, or the last of the integrated circuit units is configured to provide the sync signal to the integrated circuit units in parallel. The integrated circuit units perform synchronization according to the sync signal.

An embodiment of the disclosure provides an integrated circuit, which includes an integrated circuit unit. The integrated circuit unit has an interface. The integrated circuit unit is configured to use the interface to receive or transmit a sync signal. The plurality of integrated circuit units perform synchronization according to the sync signal

An embodiment of the disclosure provides an operation method of an electronic device, which includes the following steps. A processing unit is used to provide a register configuration in sequence. A plurality of integrated circuit units are used to receive the register configuration in sequence. After all of the integrated circuit units have received the register configuration, the processing unit is used to provide a sync signal to the integrated circuit units in parallel, or the last of the integrated circuit units is used to provide the sync signal to the integrated circuit units in parallel. The integrated circuit units perform synchronization according to the sync signal.

According to the electronic device and the operation method and the integrated circuit disclosed by the disclosure, the processing unit provides the register configuration in sequence. The integrated circuit units receive the register configuration in sequence. After all of the integrated circuit units have received the register configuration, the processing unit provides the sync signal to the integrated circuit units in parallel, or the last of the integrated circuit units provides the sync signal to the integrated circuit units in parallel. The plurality of integrated circuit units perform synchronization according to the sync signal. Therefore, the synchronization of sampling of the integrated circuit units may be effectively achieved.

### BRIEF DESCRIPTION OF THE DRAWINGS

The disclosure can be more fully understood by reading the subsequent detailed description and examples with references made to the accompanying drawings, wherein:

FIG. 1 is a schematic view of an electronic device according to an embodiment of the disclosure;

FIG. 2 is a timing diagram of an operation of an electronic device according an embodiment of the disclosure;

FIG. 3 is a flowchart of an operation method of an electronic device according to an embodiment of the disclosure; and

FIG. 4 is a flowchart of an operation method of an electronic device according to another embodiment of the disclosure.

### DETAILED DESCRIPTION OF THE DISCLOSURE

Technical terms of the disclosure are based on general definition in the technical field of the disclosure. If the disclosure describes or explains one or some terms, definition of the terms is based on the description or explanation of the disclosure. Each of the disclosed embodiments has one or more technical features. In possible implementation, a person skilled in the art would selectively implement all or some technical features of any embodiment of the disclosure or selectively combine all or some technical features of the embodiments of the disclosure.

In each of the following embodiments, the same reference number represents the same or a similar element or component.

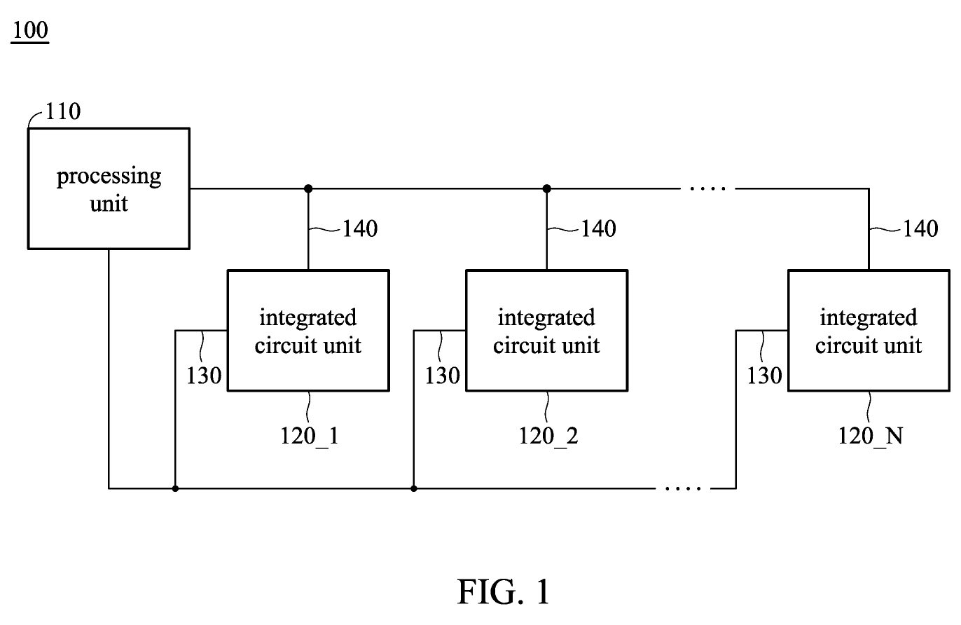

FIG. 1 is a schematic view of an electronic device according to an embodiment of the disclosure. In the embodiment, the electronic device 100 may be a portable device or a wearable device, such as a sports bracelet, but the disclosure is not limited thereto. Please refer to FIG. 1. The electronic device 100 includes a processing unit 110 and a plurality of integrated circuit units 120_1~120_N, wherein N is a positive integer greater than 1.

The processing unit 110 may provide a register configuration in sequence. The integrated circuit units 120_1~120_N may receive the register configuration in sequence. For example, firstly, the processing unit 110 may provide the register configuration to the integrated circuit unit 120_1, so that the integrated circuit unit 120_1 may receive the register configuration from the processing unit 110. Then, the processing unit 110 may provide the register configuration to the integrated circuit unit 120_2, so that the integrated circuit unit 120_2 may receive the register configuration from the processing unit 110. … Afterward, the processing unit 110 provides the register configuration to the integrated circuit unit 120_N, so that the integrated circuit unit 120_N may receive the register configuration from the processing unit 110. Accordingly, the integrated circuit units 120_1_120_N may start to set the registers according to the register configuration.

In some embodiments, after all of the integrated circuit units 120_1~120_N have received the register configuration, the processing unit 110 may provide a sync signal to the integrated circuit units 120_1~120_N in parallel. That is, after all of the integrated circuit units 120_1~120_N have received the register configuration, the processing unit 110 may serve as a master device, and the integrated circuit units 120_1~120_N may serve as slave devices. Then, the processing unit 110 may provide the sync signal to the integrated circuit units 120_1~120_N in parallel. Afterward, the integrated circuit units 120_1~120_N may perform synchronization according to the sync signal. That is, the integrated circuit units 120_1~120_N may receive the sync signal at the same time, so as to achieve synchronization of the integrated circuit units 120_1~120_N.

Alternatively, in some embodiments, after all of the integrated circuit units 120_1~120_N have received the register configuration, the last of the integrated circuit units 120_1~120_N (such as the second integrated circuit 120_N) may provide the sync signal to the integrated circuit units 120_1~120_N in parallel. That is, after all of the integrated circuit unit 120_1~120_N have received the register configuration, the integrated circuit unit 120_N that received the register configuration at last may serve as a master device, and the integrated circuit units 120_1~120_N-1 may serve as slave devices. Then, the integrated circuit unit 120_N (such as the last of the integrated circuit units 120_1~120_N) may provide the sync signal to the integrated circuit units 120_1~120_N in parallel. Afterward, the integrated circuit units 120_1~120_N may perform synchronization according to the sync signal. That is, the integrated circuit units 120_1~120_N may receive the sync signal provided by the integrated circuit unit 120_N at the same time, so as to achieve synchronization of the integrated circuit units 120_1~120_N. In the embodiment, the sync signal provided by and received by the integrated circuit unit 120_N are completed inside the integrated circuit unit 120_N.

In some embodiments, the processing unit 110 may be, for example, a micro control unit (MCU), and the integrated circuit units 120_1~120_N may be, for example, sensors, such as light sensors, but the embodiment of the disclosure is not limited thereto.

In some embodiments, each of the integrated circuit units 120_1~120_N may receive the register configuration through an interface 130. Furthermore, the interface 130 may be a serial peripheral interface (SPI) or an inter-integrated circuit (I2C). That is, in the embodiment, the processing unit 110 and the integrated circuit units 120_1~120_N may be connected through the interfaces 130.

In addition, the integrated circuit units 120_1 may receive the register configuration from the processing unit 110 through the interface 130. The integrated circuit unit 120_2 may receive the register configuration from the integrated circuit unit 120_1 through the interface 130. The integrated circuit unit 120_ 3 may receive the register configuration from to the second integrated circuit 120_2 through the interface 130. … The integrated circuit unit 120_N may receive the register configuration from the integrated circuit unit 120_N-1 through the interface 130.

In some embodiments, each of the integrated circuit units 120_1~120_N may receive the sync signal through an interface 140. Furthermore, the interface 140 may be, for example, a general-purpose input/output (GPIO) interface. That is, each of the integrated circuit units 120_1~120_N may form an integrated circuit, each of the integrated circuit units 120_1~120_N may have the interface 140, and each of the integrated circuit units 120_1~120_N may use the interface 140 to receive or transmit the sync signal.

In addition, in the embodiment, the processing unit 110 and the integrated circuit units 120_1~120_N may be connected in parallel through the interfaces 140. Accordingly, in some embodiments, the processing unit 110 may provide the sync signal to the integrated circuit units 120_1~120_N in parallel. That is, the integrated circuit units 120_1~120_N may receive the sync signal at the same time, so as to achieve synchronization of the integrated circuit units 120_1~120_N. Alternatively, in some embodiments, the integrated circuit unit 120_N may provide the sync signal to the integrated circuit units 120_1~120_N in parallel. That is, the integrated circuit units 120_1~120_N may receive the sync signal at the same time, so as to achieve synchronization of the integrated circuit units 120_1~120_N.

In some embodiments, when each of the integrated circuit units 120_1~120_N receives the sync signal, each of the integrated circuit units 120_1~120_N may identify the edge of the system clock corresponding to the sync signal as the starting point of the sampling. In some embodiments, the above edge of the system clock may include a rising edge or a falling edge of the system clock. That is, each of the integrated circuit units 120_1~120_N may identify the rising edge or the falling edge of the system clock corresponding to the sync signal as the starting point of the sampling. Then, each of the integrated circuit units 120_1~120_N may perform a sampling operation according to the starting point of the sampling, to generate sampling data.

Afterward, the processing unit 110 may read the sampling data of the integrated circuit units 120_1~120_N, so as to perform the subsequent process. For example, the processing unit 110 may read the sampling data of the integrated circuit units 120_1~120_N through the interface 130. In some embodiments, the reading sequence of the sampling data of the integrated circuit units 120_1~120_N by the processing unit 110 is not limited.

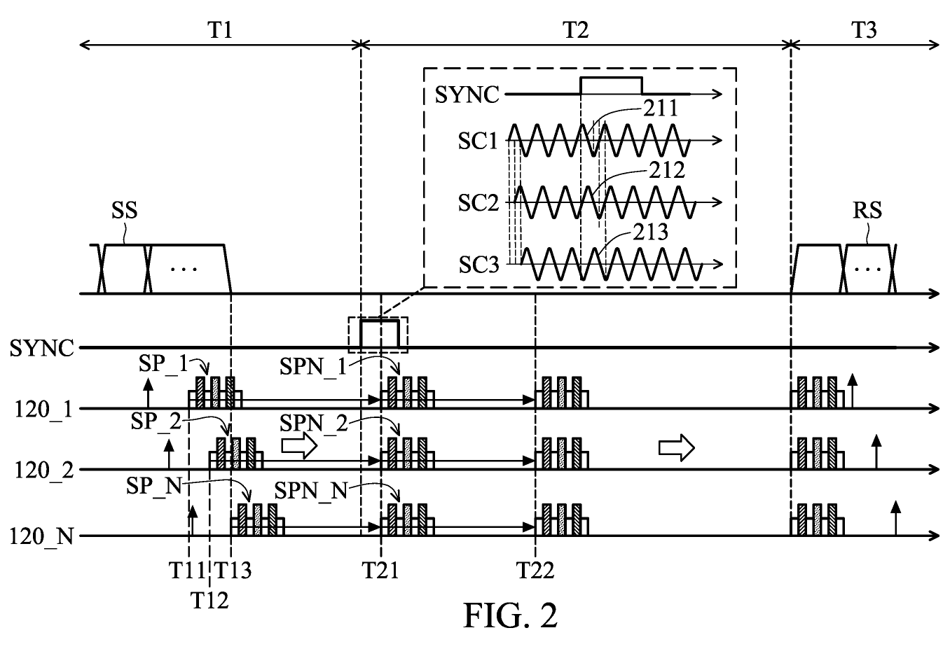

The internal components of the electronic device 100 and the coupling relationship of the internal components are described above, and the operation of the electronic device 100 is described below with a timing diagram. FIG. 2 is a timing diagram of the operation of the electronic device according an embodiment of the disclosure. Please refer to FIGS. 1 and 2.

In a setting period T1, the processing unit 110 provides the register configuration to the integrated circuit units 120_1 in sequence through the interfaces 130 (such as the SPIs or the I2Cs) according to the setting signal SS. Then, the integrated circuit units 120_1~120_N receive the register configuration from the processing unit 110 in sequence through the interfaces 130, so that the integrated circuit units 120_1~120_N may start to set the registers according to the register configuration.

After all of the integrated circuit units 120_1~120_N have received the register configuration, in a sync period T2, the processing unit 110 may provide the sync signal SYNC to the integrated circuit units 120_1~120_N in parallel through the interfaces 140 (such as the GPIO interfaces), so that the integrated circuit units 120_1~120_N may receive the sync signal SYNC at the same time. Alternatively, in the sync period T2, the integrated circuit unit 120_N (such as the last of the integrated circuit units 120_1~120_N) may provide the sync signal SYNC to the integrated circuit units 120_1~120_N in parallel through the interfaces 140 (such as the GPIO interfaces), so that the integrated circuit units 120_1~120_N may receive the sync signal SYNC provided by the integrated circuit units 120_N at the same time. In the embodiment, the sync signal provided by and received by the integrated circuit unit 120_N are completed inside the integrated circuit unit 120_N.

Then, when each of the integrated circuit units 120_1~120_N receives the sync signal SYNC, each of the integrated circuit units 120_1~120_N may start to operate and identify the edge (such as the falling edge) of the system clock corresponding to the sync signal SYNC as the starting point of the sampling. For example, the integrated circuit unit 120_1 may identify the falling edge 211 of the system clock SC1 corresponding to the sync signal SYNC as the starting point of the sampling T21 or T22. The integrated circuit unit 120_2 may identify the falling edge 212 of the system clock SC2 corresponding to the sync signal SYNC as the starting point of the sampling T21 or T22. The integrated circuit unit 120_N may identify the falling edge 213 of the system clock SC3 corresponding to the sync signal SYNC as the starting point of the sampling T21 or T22. In the embodiment, the latency of the sync signal SYNC is less than 10 nanoseconds (ns), and the latency of the clock phase of the system clock is less than 30 microseconds (us).

Afterward, each of the integrated circuit units 120_1~120_N may perform a sampling operation according to the starting point of the sampling T21 to generate the sampling data. Accordingly, the integrated circuit units 120_1~120_N may synchronously perform the sampling operation in starting point of the sampling T21 to generate the sampling data. Therefore, the synchronization of sampling of the integrated circuit units 120_1~120_N may be effectively achieved. Then, in a reading period T3, the processing unit 110 may read the sampling data of the integrated circuit units 120_1~120_N according to the reading signal RS, so as to perform the subsequent process.

In some embodiments, when each of the integrated circuit units 120_1~120_N receives the sync signal SYNC, each of the plurality of integrated circuit units 120_1~120_N may change a period of sampling (SP_1, SP_2 or SP_N) to generate a new period of the sampling (SPN_1, SPN_2, or SPN_N) based on an edge of a system clock (SC1, SC2 or SC3) corresponding to the sync signal SYNC, and each of the integrated circuit units 120_1~120_N may perform a sampling operation according to the new period of the sampling (SPN_1, SPN_2, or SPN_N) to generate sampling data, as shown in FIG. 2.

For example, when the integrated circuit units 120_1 receives the sync signal SYNC, the integrated circuit units 120_1 may change the period of sampling SP_1 to generate the new period of the sampling SPN_1 based on the edge (such as the falling edge) of the system clock SC1 corresponding to the sync signal SYNC, and the integrated circuit units 120_1 may perform the sampling operation according to the new period of the sampling SPN_1 to generate the sampling data. When the integrated circuit units 120_2 receives the sync signal SYNC, the integrated circuit units 120_2 may change the period of sampling SP_2 to generate the new period of the sampling SPN_2 based on the edge (such as the falling edge) of the system clock SC2 corresponding to the sync signal SYNC, and the integrated circuit units 120_2 may perform the sampling operation according to the new period of the sampling SPN_2 to generate the sampling data.

When the integrated circuit units 120_N receives the sync signal SYNC, the integrated circuit units 120_N may change the period of sampling SP_N to generate the new period of the sampling SPN_N based on the edge (such as the falling edge) of the system clock SC3 corresponding to the sync signal SYNC, and the integrated circuit units 120_N may perform the sampling operation according to the new period of the sampling SPN_N to generate the sampling data.

In the embodiment, as shown in FIG. 2, the period of the sampling SP_1 is aligned at the starting point T11, the period of the sampling SP_2 is aligned at the starting point T12, the period of the sampling SP_N is aligned at the starting point T13, the new period of the sampling SPN_1 is aligned at the starting point T21, the new period of the sampling SPN_2 is aligned at the starting point T21, and the new period of the sampling SPN_N is aligned at the starting point T21, wherein the starting point T11, the starting point T12 and the starting point T13. That is, the period of the sampling SP_1, the period of the sampling SP_2 and the period of the sampling SP_N are aligned different starting points T11, T12 and T13, and the new period of the sampling SPN_1, the new period of the sampling SPN_2 and the new period of the sampling SPN_N are aligned at the same starting point T21. Therefore, the integrated circuit units 120_1~120_N may perform the synchronization according to the sync signal SYNC.

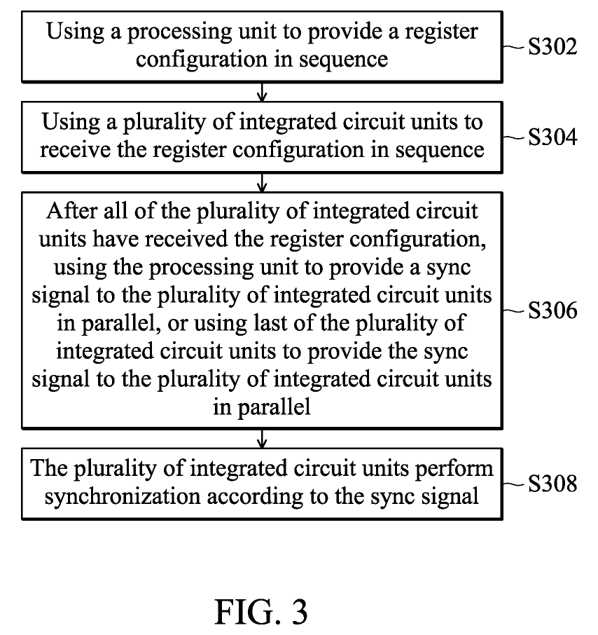

FIG. 3 is a flowchart of an operation method of an electronic device according to an embodiment of the disclosure. In step S302, the method involves using a processing unit to provide a register configuration in sequence. In step S304, the method involves using a plurality of integrated circuit units to receive the register configuration in sequence. In step S306, the method involves after all of the plurality of integrated circuit units have received the register configuration, using the processing unit to provide a sync signal to the plurality of integrated circuit units in parallel, or using last of the plurality of integrated circuit units to provide the sync signal to the plurality of integrated circuit units in parallel. In step S308, the plurality of integrated circuit units perform synchronization according to the sync signal.

In some embodiments, the processing unit is, for example, a micro control unit, and the plurality of integrated circuit units are, for example, sensors. In some embodiments, each of the plurality of integrated circuit units receives the register configuration through an interface. Furthermore, the above interface is, for example, a serial peripheral interface or an inter-integrated circuit. In some embodiments, each of the plurality of integrated circuit units receives the sync signal through an interface. Furthermore, the above interface is, for example, a general-purpose input/output interface.

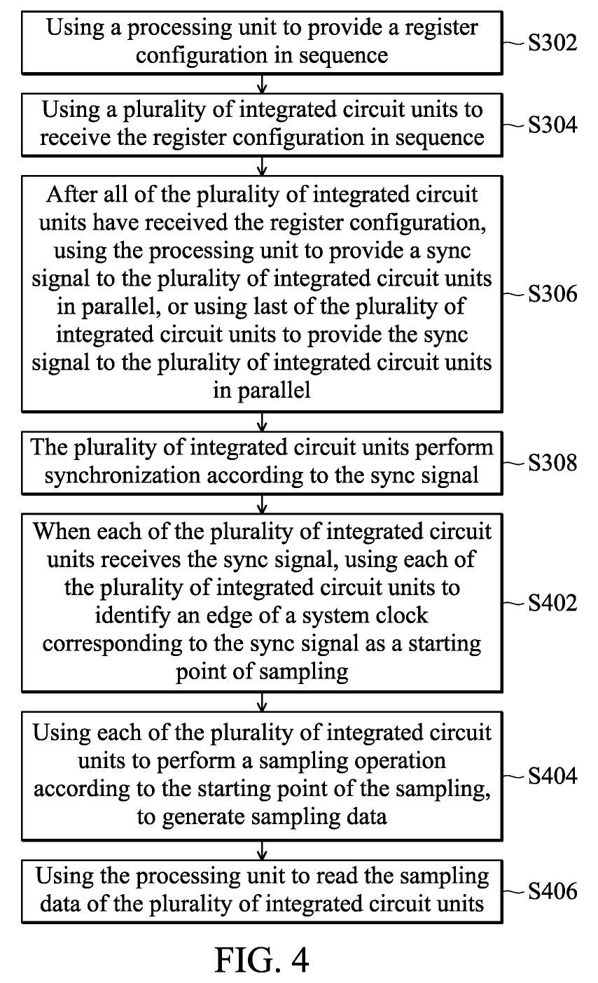

FIG. 4 is a flowchart of an operation method of an electronic device according to another embodiment of the disclosure. In the embodiment, steps S302~S308 in FIG. 4 are the same as or similar to steps S302~S308 in FIG. 3. Accordingly, steps S302~S308 in FIG. 4 may refer to the description of the embodiment of FIG. 3, and the description thereof is not repeated herein.

In step S402, the method involves when each of the plurality of integrated circuit units receives the sync signal, using each of the plurality of integrated circuit units to identify an edge of a system clock corresponding to the sync signal as a starting point of sampling. In step S404, the method involves using each of the plurality of integrated circuit units to perform a sampling operation according to the starting point of the sampling, to generate sampling data. In step S406, the method involves using the processing unit to read the sampling data of the plurality of integrated circuit units. In some embodiments, the edge of the system clock includes, for example, a rising edge or a falling edge of the system clock.

In summary, according to the electronic device and the operation method thereof and the integrated circuit disclosed by the disclosure, the processing unit provides the register configuration. The integrated circuit units receive the register configuration in sequence. After all of the integrated circuit units have received the register configuration, the processing unit provides the sync signal to the integrated circuit units in parallel, or the last of the integrated circuit unit provides the sync signal to the integrated circuit units in parallel. The plurality of integrated circuit units perform synchronization according to the sync signal. Therefore, the synchronization of sampling of the integrated circuit units may be effectively achieved.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
a processing unit, configured to provide a register configuration in sequence; and
a plurality of integrated circuit units;
wherein the plurality of integrated circuit units are configured to receive the register configuration in sequence;
wherein after all of the plurality of integrated circuit units have received the register configuration, the processing unit is configured to provide a sync signal to the plurality of integrated circuit units in parallel or last of the plurality of integrated circuit units is configured to provide the sync signal to the plurality of integrated circuit units in parallel;
wherein the plurality of integrated circuit units perform synchronization according to the sync signal.

2. The electronic device as claimed in claim 1, wherein the processing unit is a micro control unit, and the plurality of integrated circuit units are sensors.

3. The electronic device as claimed in claim 1, wherein each of the plurality of integrated circuit units receives the register configuration through an interface.

4. The electronic device as claimed in claim 3, wherein the interface is a serial peripheral interface or an inter-integrated circuit.

5. The electronic device as claimed in claim 1, wherein each of the plurality of integrated circuit units receives the sync signal through an interface.

6. The electronic device as claimed in claim 5, wherein the interface is a general-purpose input/output interface.

7. The electronic device as claimed in claim 1, wherein when each of the plurality of integrated circuit units receives the sync signal, each of the plurality of integrated circuit units identifies an edge of a system clock corresponding to the sync signal as a starting point of sampling, and each of the plurality of integrated circuit units performs a sampling operation according to the starting point of the sampling to generate sampling data.

8. The electronic device as claimed in claim 7, wherein the edge of the system clock comprises a rising edge or a falling edge of the system clock.

9. The electronic device as claimed in claim 7, wherein the processing unit reads the sampling data of the plurality of integrated circuit units.

10. The electronic device as claimed in claim 1, wherein when each of the plurality of integrated circuit units receives the sync signal, each of the plurality of integrated circuit units changes a period of sampling to generate a new period of the sampling based on an edge of a system clock corresponding to the sync signal, and each of the plurality of integrated circuit units performs a sampling operation according to the new period of the sampling to generate sampling data.

11. An integrated circuit, comprising:
an integrated circuit unit, having an interface;
wherein the integrated circuit unit is configured to use the interface to receive or transmit a sync signal;
wherein the integrated circuit unit performs synchronization according to the sync signal.

12. The integrated circuit as claimed in claim 11, wherein the interface is a general-purpose input/output interface.

13. An operation method of an electronic device, comprising:
using a processing unit to provide a register configuration in sequence;
using a plurality of integrated circuit units to receive the register configuration in sequence;
after all of the plurality of integrated circuit units have received the register configuration, using the processing unit to provide a sync signal to the plurality of integrated circuit units in parallel or using last one of the plurality of integrated circuit units to provide the sync signal to the plurality of integrated circuit units in parallel;
wherein the plurality of integrated circuit units perform synchronization according to the sync signal.

14. The operation method of the electronic device as claimed in claim 13, wherein the processing unit is a micro control unit, and the plurality of integrated circuit units are sensors.

15. The operation method of the electronic device as claimed in claim 13, wherein each of the plurality of integrated circuit units receives the register configuration through an interface.

16. The operation method of the electronic device as claimed in claim 15, wherein the interface is a serial peripheral interface or an inter-integrated circuit.

17. The operation method of the electronic device as claimed in claim 13, wherein each of the plurality of integrated circuit units receives the sync signal through an interface.

18. The operation method of the electronic device as claimed in claim 17, wherein the interface is a general-purpose input/output interface.

19. The operation method of the electronic device as claimed in claim 13, further comprising:
when each of the plurality of integrated circuit units receives the sync signal, using each of the plurality of integrated circuit units to identify an edge of a system clock corresponding to the sync signal as a starting point of sampling;
using each of the plurality of integrated circuit units to perform a sampling operation according to the starting point of the sampling to generate sampling data.

20. The operation method of the electronic device as claimed in claim 19, wherein the edge of the system clock comprises a rising edge or a falling edge of the system clock.

21. The operation method of the electronic device as claimed in claim 19, further comprising:
using the processing unit to read the sampling data of the plurality of integrated circuit units.
